(19) United States
(12) Patent Application Publication
(10) Pub. No.: US 2013/0341310 A1
(43) Pub. Date: Dec. 26, 2013

(54) MONITORING METHOD AND APPARATUS FOR EXCIMER LASER ANNEALING PROCESS

(71) Applicant: Coherent LaserSystems GmbH & Co. KG, Gottingen (DE)

(72) Inventor: Paul VAN DER WILT, Gottingen (DE)

(21) Appl. No.: 13/907,637

(22) Filed: May 31, 2013

Related U.S. Application Data
(60) Provisional application No. 61/663,435, filed on Jun. 22, 2012.

(51) Int. Cl. G01N 21/95; H01L 21/324; C30B 13/24

(52) U.S. Cl. CPC G01N 21/9501; C30B 13/24; H01L 21/324
USPC 219/121.62; 356/237.2

(57) ABSTRACT

A method is disclosed evaluating a silicon layer crystallized by irradiation with pulses form an excimer-laser. The crystallization produces periodic features on the crystalized layer dependent on the number of and energy density in the pulses to which the layer has been exposed. An area of the layer is illuminated with light. A detector is arranged to detect light diffracted from the illuminated area and to determine from the detected diffracted light the energy density in the pulses to which the layer has been exposed.

### PRIORITY CLAIM

This application claims priority of U.S. Provisional Application No. 61/663,435, filed Jun. 22, 2012, the complete disclosure of which is hereby incorporated herein by reference.

### TECHNICAL FIELD OF THE INVENTION

The present invention relates in general to melting and recrystallization of thin silicon (Si) layers by pulsed laser irradiation. The method relates in particular to methods of evaluating the recrystallized layers.

### DISCUSSION OF BACKGROUND ART

Silicon crystallization is a step that is often used in the manufacture of thin-film transistor (TFT) active-matrix LCDs, and organic LED (AMOLED) displays. The crystalline silicon forms a semiconductor base, in which electronic circuits of the display are formed by conventional lithographic processes. Commonly, crystallization is performed using a pulsed laser beam shaped in a long line having a uniform intensity profile along the length direction (long-axis), and also having a uniform or “top-hat” intensity profile in the width direction (short-axis). In this process, a thin layer of amorphous silicon on a glass substrate is repeatedly melted by pulses of laser radiation while the substrate (and the silicon layer thereon) is translated relative to a delivery source of the laser-radiation pulses. Melting and re-solidification (re-crystallization) through the repeated pulses, at a certain optimum energy density (OED), take place until a desired crystalline microstructure is obtained in the film.

Optical elements are used to form the laser pulses into a line of radiation, and crystallization occurs in a strip having the width of the line of radiation. Every attempt is made to keep the intensity of the radiation pulses highly uniform along the line. This is necessary to keep crystalline microstructure uniform along the strip. A favored source of the optical pulses is an excimer laser, which delivers pulses having a wavelength in the ultraviolet region of the electromagnetic spectrum. The above described crystallization process, using excimer-laser pulses, is usually referred to as excimer-laser annealing (ELA). The process is a delicate one, and the error margin for OED can be a few percent or even as small as ±0.5%

There are two modes of ELA. In one mode, the translation speed of a panel relative to the laser beam is sufficiently slow that the “top-hat portion” of the beam-width overlaps by as much as 95% from one pulse to the next so any infinitesimal area receives a total of about 20 pulses. In another mode referred to as advanced ELA or AELA the translation speed is much faster and in a single pass over a panel the irradiated “lines” have minimal overlap and may even leave un-crystallized space therebetween. Multiple passes are made such that the entire panel is irradiated with a total number of pulses that may be less than in an ELA process to produce equivalent material.

Whichever ELA mode is employed, evaluation of crystallized films on panels in a production line is presently done off line, by visual inspection. This inspection is entirely subjective and relies on highly trained experienced inspectors, who through their experience are able to correlate observed features of the panels with very small changes, for example less than 1%, in energy density in the crystallizing beam. In a manufacturing environment, the process of visual analysis and establishing if a change of process energy density is necessary typically takes between about one and one and one-half hours from when the crystallization was performed, with a corresponding adverse effect on production line throughput of acceptable panels.

There is a need for an objective method of evaluation of the ELA process. Preferably, the method should be capable at least of being implemented on a production line. More preferably, the method should be capable of being used for quasi real-time evaluation in a feedback loop for automatically adjusting process energy density responsive to data provided by the evaluation.

### SUMMARY OF THE INVENTION

The present invention is directed to evaluating the progress of crystallization of semiconductor layer at least partially crystallized by exposure to a plurality of laser-radiation pulses having an energy density on the layer. The crystallization produces first and second groups of periodic surface features on the layer in respectively first and second directions perpendicular to each other, the form of the first and second groups of periodic features depending on the energy density of the laser-radiation pulses to which the semiconductor laser has been exposed.

In one aspect of the present invention an evaluation method comprises delivering light to an area of the crystallized semiconductor layer such that first and second portions of the light are diffracted by respectively the first and second groups of periodic features. The amplitudes of the first and second diffracted light portions are separately measured. The energy density on the layer of the laser-radiation pulses is determined from the measured amplitudes of the first and second diffracted light portions.

### BRIEF DESCRIPTION OF THE DRAWINGS

The accompanying drawings, which are incorporated in and constitute a part of the specification, schematically illustrate a preferred embodiment of the present invention, and together with the general description given above and the detailed description of the preferred embodiment given below, serve to explain principles of the present invention.

FIG. 1 is a graph schematically illustrating measured peak amplitude as a function of pulse energy density in rolling and transverse direction for fast Fourier transforms (FFTs) of scanning laser microscope images of ELA crystallized silicon layers.

FIG. 2 is a graph schematically illustrating measured peak amplitude as a function of pulse energy density in rolling and transverse directions for FFTs of scanning laser microscope images of A-ELA crystallized silicon layers.

FIG. 3 is a graph schematically illustrating measured peak amplitude as a function of pulse number in rolling and transverse direction for fast Fourier transforms (FFTs) of scanning laser microscope images of A-ELA crystallized silicon layers.

FIG. 4 is a polarized-light microscope image of an area of an ELA crystallized silicon layer illustrating ridges formed transverse to and parallel to the rolling direction (RD) of the layer during crystallization.

FIG. 5 is a conoscopic microscope image of an area of a crystallized layer similar to that of FIG. 4 depicting horizontal and vertical bands of light formed by diffracted light from respectively transverse-direction and rolling-direction ridges.

FIG. 6 is a graph schematically illustrating measured amplitude as a function of pulse-energy density for diffracted light from transverse-direction and from rolling-direction ridges of ELA crystallized layers.

FIG. 7 is a graph schematically illustrating measured amplitude as a function of pulse number for diffracted light from transverse-direction and from rolling-direction ridges of A-ELA crystallized layers for EDs of 410, 415, and 420 mJ/cm².

FIGS. 8 and 8A schematically illustrate one preferred embodiment of an apparatus in accordance with the present invention for separately measuring the amplitude of diffracted light from transverse-direction and from rolling-direction ridges of ELA crystallized layers.

FIG. 9 schematically illustrates one preferred embodiment of ELA apparatus in accordance with the present invention including the apparatus of FIG. 8 cooperative with a variable attenuator for adjusting pulse energy density on a silicon layer responsive to the measured amplitude of diffracted light from transverse-direction and from rolling-direction ridges of the ELA crystallized layer.

FIG. 10 schematically illustrates another preferred embodiment of an ELA apparatus in accordance with the present invention similar to the apparatus of FIG. 9, but wherein the apparatus of FIG. 8 is replaced by another preferred embodiment of an apparatus in accordance with the present invention for separately measuring the amplitude of diffracted light from transverse-direction and from rolling-direction ridges of the ELA crystallized layer.

### DETAILED DESCRIPTION OF THE INVENTION

ELA processing of thin Si films leads to formation of surface roughness: protrusions are formed as a result of the expansion of Si upon solidification; they are formed especially between three or more solidification fronts colliding during lateral growth. The protrusions are often not randomly located. Rather, they are aligned due to processes of ripple formation collectively referred to in the literature as laser-induced periodic surface structures (LIPSS). The ripples thus consist of series of well aligned protrusions. The ripple formation is only observed within an energy density window (range) in which partial melting of the film is achieved. Typically the ripple periodicity is on the order of the wavelength of the incident light, for example, around 290-340 nm for XeCl excimer lasers. Because of these small dimensions, ripples cannot or can at best hardly be resolved using conventional optical microscopy techniques.

What is typically observed in optical bright field microscopy is that the surface of ELA processed films consists of elongated darker colored regions interspersed with brighter regions. Close inspection of the darker regions shows that they consist of more strongly rippled (ordered) regions having higher protrusions, while in between are regions having less order and/or lower protrusions. The more ordered regions are herein referred to as ridges, while the regions in between are referred to as valleys. It is an inventive finding that the formation of ridges appears to be correlated to that of ripples with the typical orientation of ridges being in a direction perpendicular to the ripple direction. The inventive method and apparatus rely on measuring light-diffraction from ridges in a thin Si film (layer) that are formed as a result of the ELA process. The method offers an indirect measure of the degree of rippling that can be used for monitoring or controlling the ELA process in quasi real-time. In addition, a method is described looking more directly at the ripples themselves, albeit using microscopy techniques that are relatively slow compared to more conventional optical microscopy techniques used for measuring diffraction from ridges.

Ripples are commonly not formed in one direction only. The ripples are predominantly formed in a direction parallel to the scan direction, and also in a direction perpendicular to the scan direction (the line direction). The ripples are periodic and are described herein by the direction of their periodicity, using terminology common in metallurgy, wherein the rolling direction (RD) corresponds with the scanning direction and the transverse direction (TD) corresponds with the line-direction. Accordingly, since ripples oriented in the scan direction are periodic in the transverse direction, they are termed TD ripples. Similarly ripples oriented in the line direction are periodic in the rolling direction and are termed RD ripples.

In accordance with LIPSS theory, TD ripples have a spacing roughly equal to the wavelength of the light, while RD ripples are spaced approximately λ/(1±sin θ), with the λ/(1−sin θ) spacing typically dominant, wherein θ is the angle of incidence of laser-radiation on the layer, which in ELA typically is about 5 or more degrees. Ripple formation is instrumental in obtaining uniform poly-Si films, because the grain structure tends to follow the surface periodicity. When ripples are present, ideally, a very ordered film consisting predominantly of rectangular grains sized roughly λ by λ/(1−sin θ) is formed. At lower energy density (ED), grains are smaller and at higher ED, grains are larger. When grains larger than the ripple domain size are grown, herein referred to as super-lateral growth (SLG), surface reflow will result in reduction of the protrusion height and a gradual loss of the order in the film.

In a first experiment to determine a numerical relationship between surface periodicity caused by the ripples and ED of laser pulses, laser scanning microscope (LSM) images of crystallized films were analyzed by fast Fourier transform (FFT), with transforms made in the RD and TD directions. A peak in the FFT indicates the existence of a certain surface periodicity and the location of the peak corresponds to the direction of the surface periodicity. The TD-transform provided sharp peaks at about 1/λ indicating strong TD periodicity. RD transforms showed peaks less sharp at about (1−sin θ)/λ and with lower amplitude than those of the TD transforms, i.e., less pronounced RD ripples with about (1−sin θ)/λ spacing.

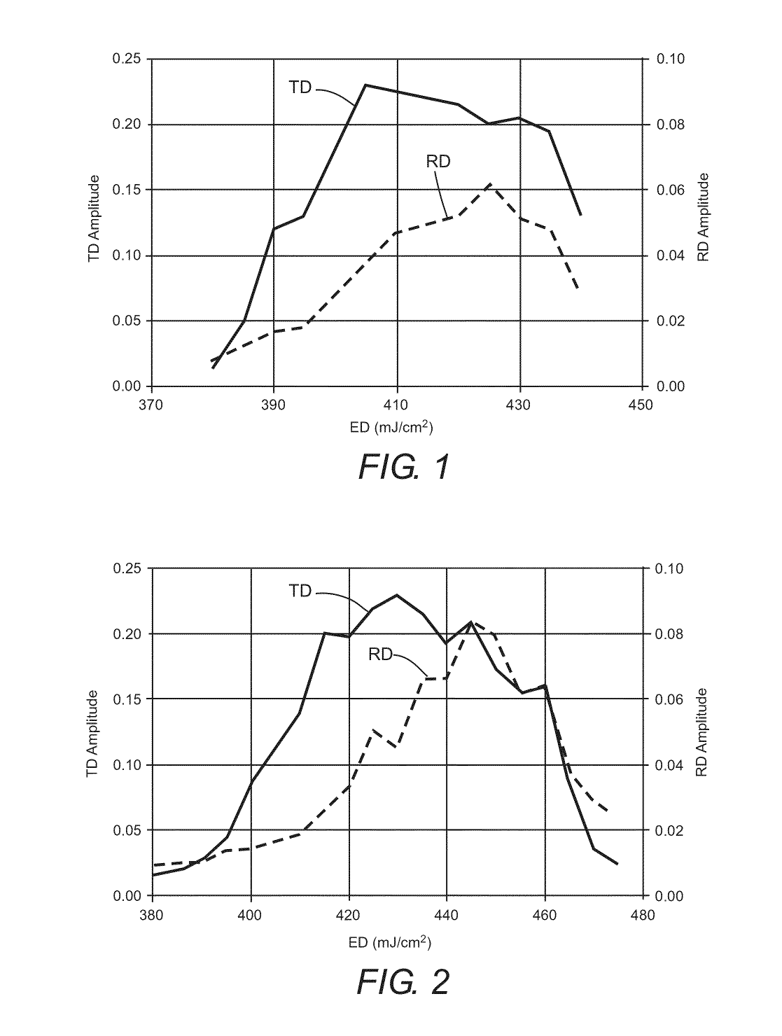

FIG. 1 is a graph schematically illustrating amplitude of corresponding RD and TD transform peaks as a function of energy density (ED) in millijoules per square centimeter (mJ/cm²) in pulses for a total of 25 overlapping pulses in an ELA process. It can be seen that the RD periodicity appears to be greatest at a slightly higher ED than that for which TD periodicity is greatest. Here an OED of about 420 mJ/cm² is indicated with periodicity in both RD and TD directions decreasing (relatively) sharply with higher ED. It should be noted here that the ED as defined herein is determined using an approach common in industry involving measuring the power in the beam and dividing that by the top hat width of the beam, ignoring any gradients on either side of the top hat.

FIG. 2 is a graph similar to the graph of FIG. 1 but for crystallization by an A-ELA process of 25 pulses. Here, the RD ripples show stronger periodicity than for ELA and its peak periodicity is better defined than in the case of the ELA process.

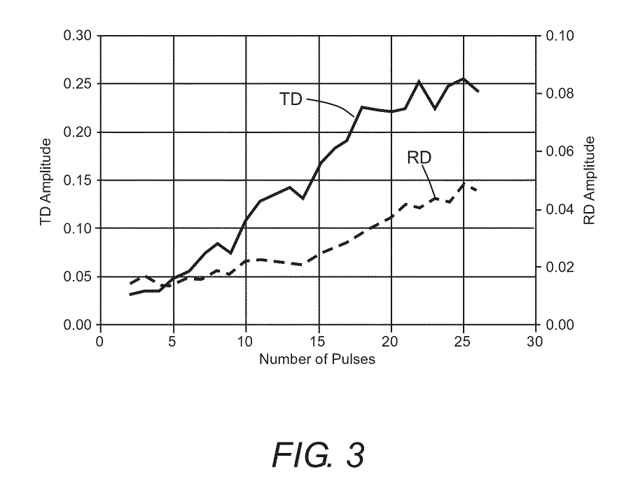

FIG. 3 is a graph schematically illustrating RD and TD peak amplitudes as a function of pulse number at an ED of 420 mJ/cm², which is somewhat less than the empirically determined OED. It can be seen that periodicity increases steadily in the TD direction up to a pulse number of about 22. In the RD direction, there is very little growth of periodicity until after about 15 pulses have been delivered.

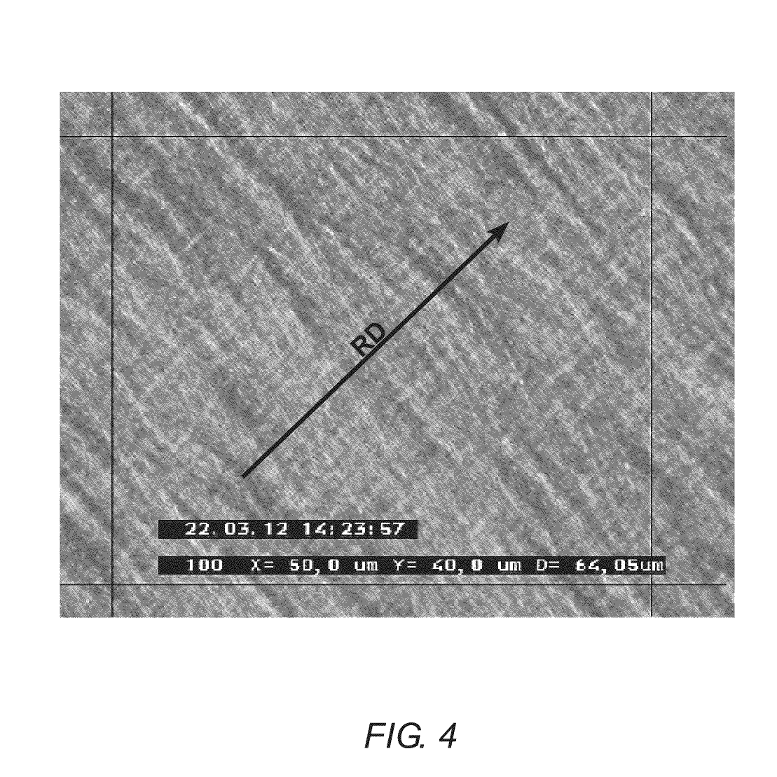

FIG. 4 is a polarization microscope image in reflected light. Ridges that are oriented in the transverse direction (which are correlated to ripples in the RD direction, or in other words, following the periodicity based definition, the “TD-ripples”) can clearly be seen. Ridges that are oriented in the rolling direction (and correlated to “RD ripples”) are less prominent but still evident, as would be expected from the above discussed FFT analysis.

Unlike ripples, the ridges are not strictly periodic. However, the ridges have a characteristic spacing that can typically range between about 1.5 μm and about 3.0 μm, or about an order of magnitude larger than the spacing between the ripples. In accordance with the terminology of ripples the ridges are referred to in the direction of periodicity, i.e., RD ridges are oriented in the transverse direction and TD ridges are oriented in the rolling direction.

The FFT analysis, in itself, clearly provides one means of evaluating a crystallized layer. However, the steps required to generate the above discussed information are generally slow and would not encourage use of such analysis for near real-time on-line monitoring or evaluation of a layer crystallized by ELA or A-ELA. Accordingly, it was decided to investigate the possibility of analyzing diffraction phenomena associated with the perpendicularly oriented groups of ridges associated with RD and TD ripples, rather than attempting to directly measure the ripples themselves.

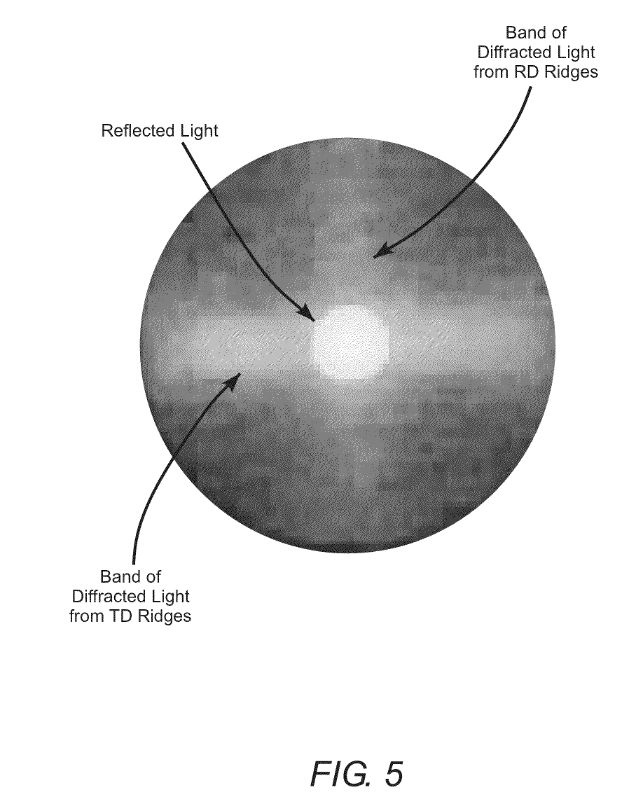

FIG. 5 is a conoscopic microscope image of a layer such as that depicted in FIG. 4. This was taken using a commercially available microscope with the eyepiece removed to allow an image of the back focal plane of the objective to be recorded. In this example, the image was recorded with a simple mobile-telephone camera. The microscope was used in a transmitted light configuration. A first polarizer was located in the illumination light path ahead of the sample and a second polarizer (analyzer) was located after the sample with the polarization direction at 90-degrees to that of the first polarizer.

The center of the conoscopic image corresponds to the optical axis of the microscope system and the distance from the optical axis (center spot) corresponds to the angle over which the light travels. Accordingly, the conoscopic image provides information on the direction of light in the microscope.

A condenser diaphragm was set close to a minimum aperture to limit the angular distribution of incident light on the sample and consequently to restrict the image of the aperture to the center of the conscopic image. The remainder of the image is formed by light diffracted from the TD and RD ridge groups formed by the crystallization. The polarizer and analyzer, together, act to minimize the brightness of the central spot relative to the rest of the image. At 90-degrees relative rotation the two polarizers form a pair of crossing bands of extinction, known as isogyres, in the conoscopic image. By rotating polarizer and analyzer together with respect to the sample, the isogyres can be rotated away from the diffraction bands to minimize extinction of the bands.

The actual image represented in gray-scale in FIG. 5 is a colored image. The horizontal band is a bluish color and the vertical band is a greenish color. The coloring of the bands can be quite uniform and is believed to be indicative of a high diffraction efficiency at those wavelengths and lower diffraction efficiency at other wavelengths. The uniformity of the coloring of the bands is believed to be a result of variable spacing of the ridges. There may be some spectral overlap between the spectra of the horizontal and vertical bands.

The microscope objective was a 20× objective. A fragmented edge of the central spot where the intensity gradient is high gives an indication of the image pixel size. The larger squares in the dark quadrants are an artifact of JPEG image-compression.

In a horizontal direction of the figure there is a strong band of light resulting from diffraction by RD ridges (as related to TD ripples). In the vertical direction of the figure, there is weaker band of light resulting from diffraction by TD ridges (as related to RD ripples). Transmitted light forms a bright spot in the center of the image.

As would be expected from the graphs of FIG. 1 and FIG. 2, as the pulse ED falls below the OED, the relative brightness of the TD-ridge diffraction band relative to the brightness of the RD-ridge diffraction band decreases steeply with decreasing ED. When the pulse ED rises above the OED, the relative brightness of the TD-ridge diffraction band compared to the brightness of the RD-ridge diffraction band remains about the same, but both fall steeply with increasing ED. Measuring the brightness of the diffraction bands thus provides a powerful method of determining whether ED is above or below OED and by how much.

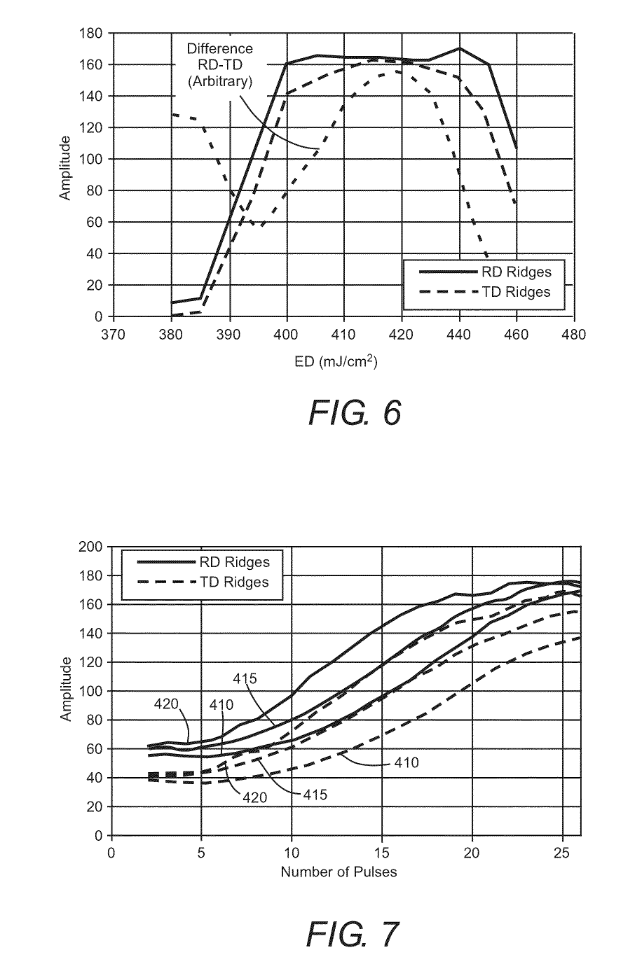

FIG. 6 is a graph schematically illustrating RD ridge diffraction intensity (solid curve) and TD ridge diffraction intensity (dashed curve) as a function of pulse ED for a silicon layer area crystallized by 25 overlapping pulses in an ELA process. The intensity of ridges was not measure directly. Instead, a measure for diffraction band intensity was devised based on the observation that the bands have different color and that color information is still present in the regular microscope image.

A commercially available raster graphics editor was used to determine the mean brightness of the blue and green channels of polarized light images as a measure of the diffraction of RD ridges and TD ridges, respectively. A disadvantage of this approach is that the image color channels do not provide optimized filtering to see the band brightness so that there is quite a significant cross-talk between the two signals. Also the signal of the non-diffracted central spot is superimposed on these color channels so that they have a higher noise level. Even so, the difference clearly shows a trend, with the OED found when the ratio of the green channel brightness to the blue channel brightness reaches a maximum, as depicted in FIG. 6 by the dotted curve.

Alternatively a conoscopic image recorded by a CMOS array or CCD array, similar to the image of FIG. 5 can be electronically processed, using appropriate software, to gather measurement data only from the diffraction bands. This has an advantage that the measurement would be insensitive to the actual color and diffraction efficiency of the diffracted light bands in the image, as the spatial information is essentially independent of this. The actual diffraction efficiency may be a function of film thickness and deposition parameters.

FIG. 7 is a graph schematically illustrating RD-ridge diffraction-intensity (solid curves) and TD-ridge diffraction-intensity (dashed curves) as a function of pulse number and ED for pulses sequentially delivered to the same area of a layer being crystallized. The trend here is similar to that of the graph of FIG. 3. The three ED values in each case are 410 mJ/cm², 415 mJ/cm², and 420 mJ/cm², i.e., selected at intervals of little over 1% of the ED. It can be seen that after 15 pulses are deposited the 1% change in ED gives rise to a change of about 20% in signal amplitude. At around 22 pulses, the diffracted signal change is still on the order of 5% or better for the 2% change in ED. This clearly illustrates the sensitivity of the inventive method.

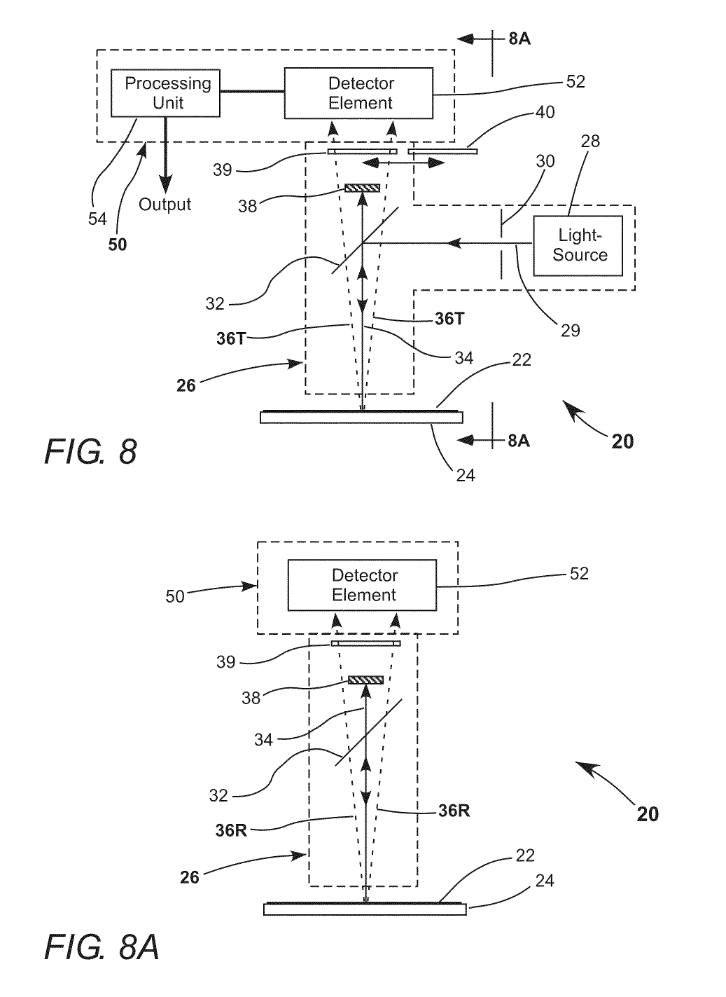

FIG. 8 schematically illustrates one preferred embodiment 20 of apparatus in accordance with the present invention for evaluating a crystallized silicon layer. Here a crystallized silicon layer 22 being evaluated is supported on a glass panel 24. A microscope 26 set up for Köhler illumination includes a lamp or light source 28 delivering a beam 29 of white light. A condenser diaphragm 30 provides for control of the numerical aperture of the light cone of beam 29.

A partially reflective and partially transmissive optical element 32 (a beamsplitter) directs beam 29 onto layer 22 at normal incidence to the layer as depicted in FIG. 8. A portion 34 of the light beam is reflected from layer 22 and portions 36T are diffracted. The suffix T, as used here, means that the light is diffracted by above-described transverse-direction (TD) ridges formed during crystallization of the layer. FIG. 8A depicts apparatus 20 in a plane perpendicular to the plane of FIG. 8 and illustrates light 36R diffracted by above-described rolling-direction (RD) ridges formed during crystallization of the layer.

The reflected and diffracted light is transmitted through element 32. The reflected light is blocked by a stop 38. The diffracted light by-passes stop 38 and is incident on an optical detector element 52 in a detector unit 50. An electronic processor 54 is provided in detector unit 50 and is arranged to determine the amplitude of the diffracted light received by the detector.

Detector element 52 can be a pixelated detector such as a CCD array or a CMOS array as discussed above, recording a conoscopic image of the diffracted light (see FIG. 7) from which the diffracted light intensity can be determined by processor 54 by spatial analysis. Alternatively, the detector element can be a one or more photo-diode elements recording aggregate diffracted light. For this case, optional filter elements 39 and 40 are provided having pass-bands selected to correspond to the particular colors of the TD and RD diffracted light, as discussed above. These can be moved in or out of the diffracted-light path as indicated in FIG. 8 by arrows A.

In either case, another spectral filter (not shown) can be provided for limiting the bandwidth of light from source 28 to those colors which are diffracted. This will reduce noise due to scattered light (not shown) from layer 22, that is able to by-pass stop 38 and mix with the diffracted light.

In FIGS. 8 and 8A optics of microscope 26 including collector lens optics for light source 28, (infinity-corrected) objective optics, and tube lens optics are not shown, for convenience of illustration. Additionally, the microscope can be provided with a Bertrand lens to directly observe the conoscopic image and “eye pieces” (or oculars). The form and function of such optics in a microscope is well known to those familiar with the optical art, and a detailed description thereof is not necessary for understanding principles of the present invention.

Alternative to a reflected light microscope, a transmitted light microscope may be used. Such a microscope setting does not have a beamsplitter but does require a separate condenser lens ahead of the sample. For best results the beam stop 38 may be placed in the back focal plane of the objective or in any conjugate plane thereof after the sample. For reflected light microscopy, the beam stop is best placed in a conjugate plane to the back focal plane of the objective that is located after the beamsplitter so as to not also block the incoming light.

It should be noted that the diffraction from ridges was observed also in the absence of polarizers and/or a beam stop. Diffraction bands could also still be observed after removal of the objective and/or the condenser lenses. Such lenses should thus be seen as a tool to optimize the measurement in terms of brightness and selectivity of the region within the film that is being probed. They are not critical elements of the apparatus described herein.

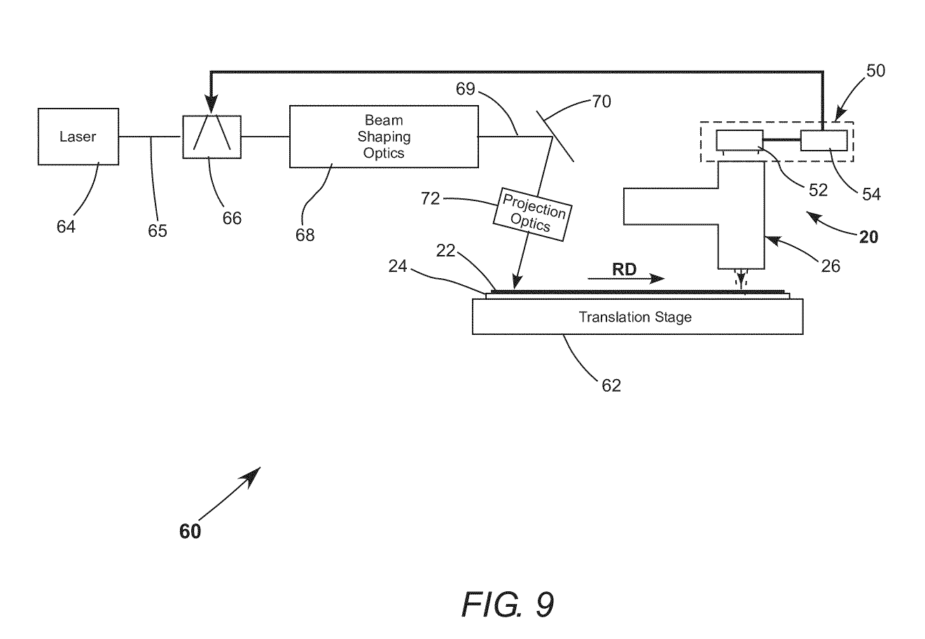

FIG. 9 schematically illustrates one preferred embodiment 60 of an excimer laser annealing apparatus in accordance with the present invention. Apparatus 60 includes an excimer laser 64 delivering a laser beam 65. Beam 65 is transmitted through a variable attenuator 66 to beam-shaping optics 68 which deliver a shaped beam 69 via a turning mirror 70 to projection optics 72. The projection optics project the beam onto layer 22 at non-normal incidence as discussed above. Glass panel 24 including layer 22 is supported on a translation stage 62 which moves the layer and panel in a direction RD relative to the projected laser beam.

Above-described apparatus 20 is positioned above layer 22. Processing unit 54 determines from the amplitude of the TD-ridge diffracted and RD ridge diffracted light components observed by detector element 52 and an electronic look-up table created from experimental curves such as the curves of FIG. 6 and FIG. 7 whether the layer has been crystallized with pulses above or below the OED.

Typically the energy density in the projected laser beam (pulse energy or process ED) is initially controlled at the nominal OED. The delivered energy density, however, may drift with time, which is usually recorded as an apparent drift of the OED. If the OED appears to have drifted to a lower value than nominal, the ED will be below the OED; there will be a lower density of ridges in both directions as discussed above; and, accordingly, both the diffraction signals will be reduced in magnitude. A signal is then sent from processing unit 54 to attenuator 66 to reduce the pulse energy delivered to the layer. If the OED appears to have drifted to a higher value than nominal, the ED will be below the instant OED; there will be a lower density of RD ridges relative to TD ridges discussed above; and, accordingly, both the RD ridge diffraction magnitude will decrease while the TD diffraction magnitude remains the same. A signal is then sent from processing unit 54 to attenuator 66 to appropriately increase the pulse energy delivered to the layer.

The above-described correction process does not, of course, have to be done automatically using the feedback arrangement of FIG. 9. Alternatively, processing unit 54 can deliver information concerning the apparent OED drift for display on a monitor to an operator, and the operator can manually adjust the pulse-energy delivered to layer 22.

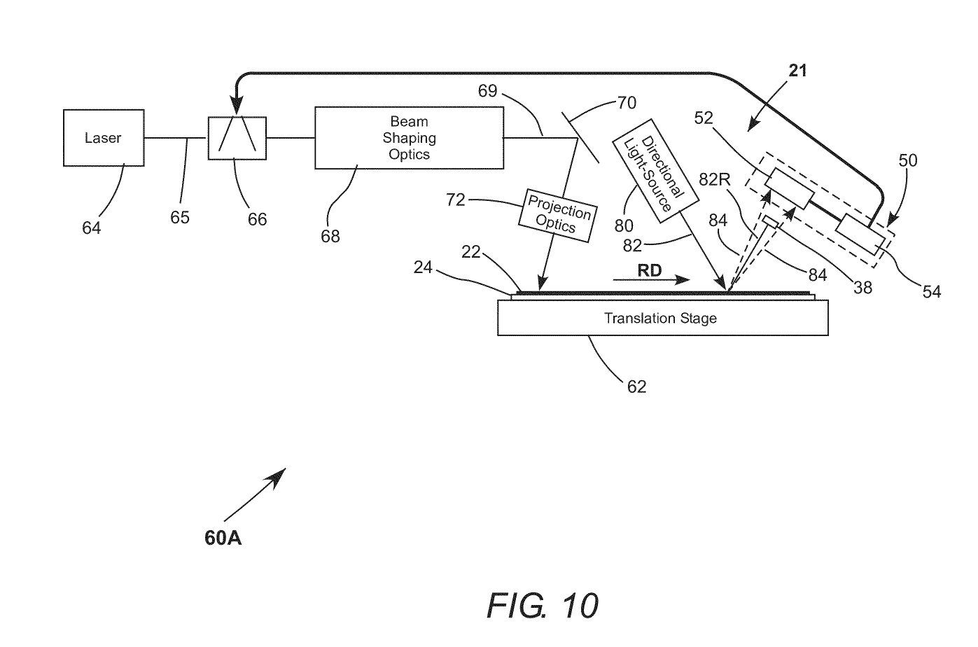

FIG. 10 schematically illustrates another preferred embodiment 60A of excimer laser annealing apparatus in accordance with the present invention. Apparatus 60A is similar to apparatus 60 of FIG. 9 with an exception that diffraction measuring apparatus 20 thereof is replaced by an alternative diffraction measuring apparatus 21 which includes a directional light source 80 such as a laser beam 82. The light from the laser is incident on layer 22 at non-normal incidence as depicted in FIG. 10, producing a reflected beam 82R and diffracted light 84. There will be diffracted light beams from TD-ridges and from RD-ridges as described above with reference to apparatus 20 of FIG. 8 and FIG. 9. The reflected beam 82R is optionally blocked by stop 38 and diffracted light is detected by detector element 52 and can be processed by processing unit 54 as described above depending on the form of detector element 52.

The inventive method and apparatus may thus be used to find OED from a panel containing multiple scans each at a different ED for example with ED 10, 5, or even just 2 mJ/cm² apart. A microscope according to the present invention may be mounted inside an annealing chamber of laser annealing apparatus. The microscope may include a zoom-lens assembly to change the magnification. The panel can be scanned underneath the microscope to allow the panel to be measured at one or multiple locations per condition. The microscope may additionally be provided with a stage to make movements in the transverse direction. An automatic focusing arrangement may be added but this will not be necessary for a conoscopic image as this has a larger depth of focus than the ELA process. Fully crystallized panels can also be measured (either online or offline) in one or more locations to detect the quality of the process so that the crystallization of further panels may be interrupted if necessary. If sufficient measurements are carried out, a map of defects (mura) may be obtained.

It should be noted here that while the present invention is described with reference to evaluating ELA and A-ELA crystallized silicon layers, the invention is applicable to evaluating crystallized layers of other semiconductor materials. By way of example, layers of germanium (Ge) or Ge and Silicon alloy make be evaluated.

In summary, while the invention is described above in terms of a preferred and other embodiments, the invention is not limited to the embodiments described and depicted. Rather, the invention is limited only by the claims appended hereto

What is claimed is:

1. Optical apparatus for evaluating a semiconductor layer at least partially crystallized by exposure to a plurality of laser-radiation pulses having an energy density on the layer, the crystallization producing a first group of periodic surface features on the layer in a first direction, the form of the first group of periodic features depending on the energy density of the laser-radiation pulses to which the semiconductor layer has been exposed, the apparatus comprising:
a light-source arranged to deliver light to an area of the crystallized semiconductor layer such that a first portion of the light is diffracted by the first group of periodic features; and
a detector and processing electronics arranged to detect the first light portion diffracted from the illuminated area and determine from the detected diffracted first light portion the energy density on the semiconductor layer of the pulses to which the semiconductor layer has been exposed.

2. The apparatus of claim 1 further having a second group of periodic surface features on the layer in a second direction at an angle with the first direction such that a second portion of the light is diffracted by the second group of periodic features and such second portion of the light also being detected by the detector and processing electronics.

3. The apparatus of claim 2, wherein the angle between the first and the second direction is about 90 degrees.

4. The apparatus of claim 1, wherein the semiconductor layer is a silicon layer.

5. Optical apparatus for at least partially crystallizing a semiconductor layer on a substrate, comprising:
a laser and projection optics for delivering a plurality of laser-radiation pulses to the semiconductor layer on the substrate for causing the crystallization;
a variable attenuator for selectively varying the energy density of the laser radiation pulses incident on the layer to control the degree of crystallization of the layer;
a translation stage for translating the substrate and the semiconductor layer thereon in a translation direction relative to the incident laser-radiation pulses the crystallization and translation of the semiconductor layer producing a first group of periodic surface features on the layer in a first direction, the form of the first group of periodic features depending on the energy density of the laser-radiation pulses to which the semiconductor layer has been exposed;
a light-source arranged to deliver light to an area of the crystallized semiconductor layer such that a first portion of the light is diffracted by the first group of periodic features; and
a detector and processing electronics arranged to detect the first light portion diffracted from the illuminated area and determine from the detected diffracted first light portion the energy density on the semiconductor layer of the pulses to which the semiconductor layer has been exposed, and if the determined energy density is above or below an optimum energy density (OED) for the crystallization, to selectively adjust the variable attenuator such that the energy on the semiconductor layer of the pulses is at about the OED.

6. The apparatus of claim 5, wherein the crystallization and translation of the semiconductor layer further produces a second group of periodic surface features on the layer in a second direction at an angle to the first direction, such that a second portion of the light is diffracted by the second group of periodic features and wherein the detector and processing electronics are arranged to detect the first and second light portions diffracted from the illuminated area and determine from the detected diffracted first and second light portions the energy density on the semiconductor layer of the pulses to which the semiconductor layer has been exposed.

7. The apparatus of claim 6, wherein the angle between the first and the second direction is about 90 degrees.

8. The apparatus of claim 6, wherein the first direction is in the translation direction of the semiconductor layer.

9. The apparatus of claim 5, wherein the semiconductor layer is a silicon layer.

10. The apparatus of claim 5, wherein the light source delivers the light at normal incidence to the semiconductor layer.

11. The apparatus of claim 5, wherein the light source delivers the light at non-normal incidence to the semiconductor layer.

12. A method of evaluating a semiconductor layer at least partially crystallized by exposure to a plurality of laser-radiation pulses having an energy density on the layer, the crystallization producing first and second groups of periodic surface features on the layer in respectively first and second directions perpendicular to each, the form of the first and second groups of periodic features depending on the energy density of the laser-radiation pulses to which the semiconductor layer has been exposed, the method comprising:
delivering light to an area of the crystallized semiconductor layer such that first and second portions of the light are diffracted by respectively the first and second groups of periodic features;
separately measuring the amplitudes of the first and second diffracted light portions; and
determining the energy density on the layer of the laser-radiation pulses from the measured amplitudes of the first and second diffracted light portions.
